(19) United States
(12) Patent Application Publication
(10) Pub. No.: US 2025/0043414 A1
(43) Pub. Date: Feb. 6, 2025

(54) FILM-FORMING METHOD AND FILM-FORMING APPARATUS

(71) Applicant: Tokyo Electron Limited, Tokyo (JP)

(72) Inventor: Kazumi KUBO, Iwate (JP)

(21) Appl. No.: 18/778,072

(22) Filed: Jul. 19, 2024

(30) Foreign Application Priority Data
Aug. 2, 2023 (JP) 2023-126109

(51) Int. Cl. C23C 16/30; C23C 16/455; C23C 16/458; C23C 16/56

(52) U.S. Cl. CPC C23C 16/308; C23C 16/455; C23C 16/4584; C23C 16/56

(57) ABSTRACT

A film-forming method for forming a titanium oxynitride film on a substrate includes: (a) supplying a titanium-containing gas to the substrate; and (b) supplying an oxidizing gas to the substrate to which the titanium-containing gas is supplied, and supplying a shape control gas to an area same as that to which the oxidizing gas is supplied, thereby adjusting a shape of the titanium oxynitride film.

### CROSS-REFERENCE TO RELATED APPLICATIONS

This application is based upon and claims priority to Japanese Patent Application No. 2023-126109, filed on Aug. 2, 2023, the entire contents of which are incorporated herein by reference.

### BACKGROUND

### 1. Field of the Invention

The present disclosure relates to film-forming methods and film-forming apparatuses.

### 2. Description of the Related Art

Japanese Patent Application Publication No. 2019-102807 discloses a protective film-forming method of forming a protective film on a flat region (or a projecting region) between a plurality of recesses formed at the surface of a substrate. This protective film-forming method forms an oxide film of an organic metal or an organic semimetal in the flat region, and further etches the side surface of the oxide film.

Meanwhile, removal (e.g., peeling) of a titanium oxide (TiO) film that is an oxide film formed on a substrate is known to be demanding. In view of this, it is conceivable to form a titanium oxynitride (TiON) film, which is readily removable, on the surface of a substrate when removal (e.g., peeling) thereof is to be performed.

### SUMMARY

According to an aspect of the present disclosure, a film-forming method for forming a titanium oxynitride film on a substrate includes: (a) supplying a titanium-containing gas to the substrate; and (b) supplying an oxidizing gas to the substrate to which the titanium-containing gas is supplied, and supplying a shape control gas to an area same as that to which the oxidizing gas is supplied, thereby adjusting a shape of the titanium oxynitride film.

### BRIEF DESCRIPTION OF THE DRAWINGS

FIG. 1 is a cross-sectional view schematically illustrating a film-forming apparatus according to an embodiment;

FIG. 2 is a plan view schematically illustrating the interior of a process chamber of the film-forming apparatus;

FIG. 3 is a partial cross-sectional view of a range of the process chamber including a raw material gas nozzle, a separation gas nozzle, and a reaction gas nozzle, taken along a concentric circle of a rotation table;

FIG. 4 is a flowchart of a film-forming method performed by the film-forming apparatus;

FIG. 5 is a graph illustrating percentages of elements of a titanium oxynitride film formed by the film-forming method;

FIG. 6A is enlarged cross-sectional views each illustrating a projection of a substrate W on which a film is formed; and

FIG. 6B is a graph obtained by analyzing the state of a film formed at the projection.

### DETAILED DESCRIPTION OF THE INVENTION

The present disclosure provides a technique of readily forming a titanium oxynitride film into a target shape.

Hereinafter, embodiments of the present disclosure will be described with reference to the drawings. In the drawings, the same components are denoted by the same reference symbols, and duplicate description thereof may be omitted.

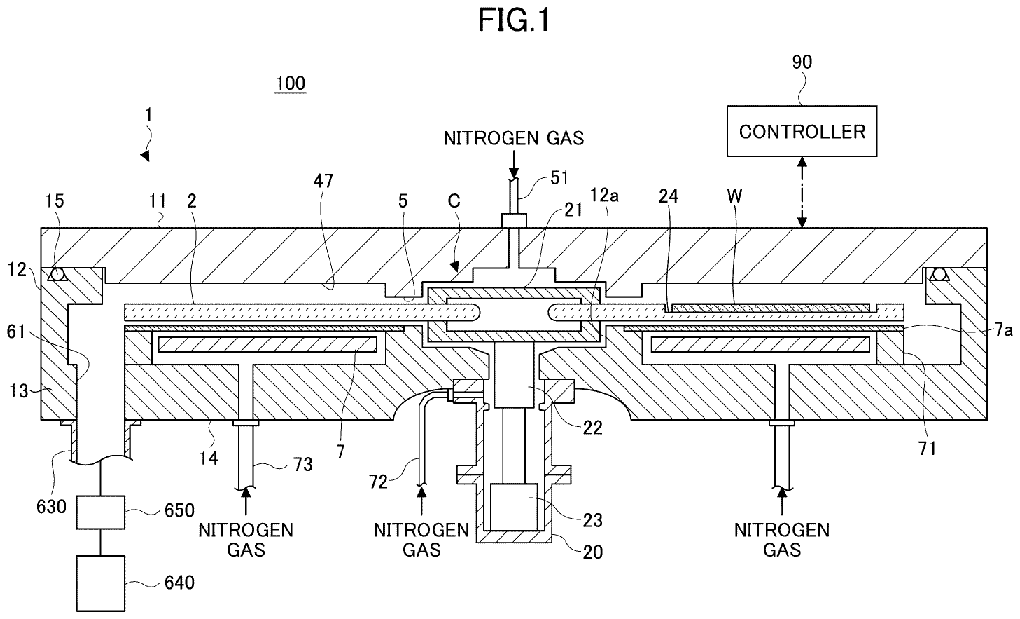

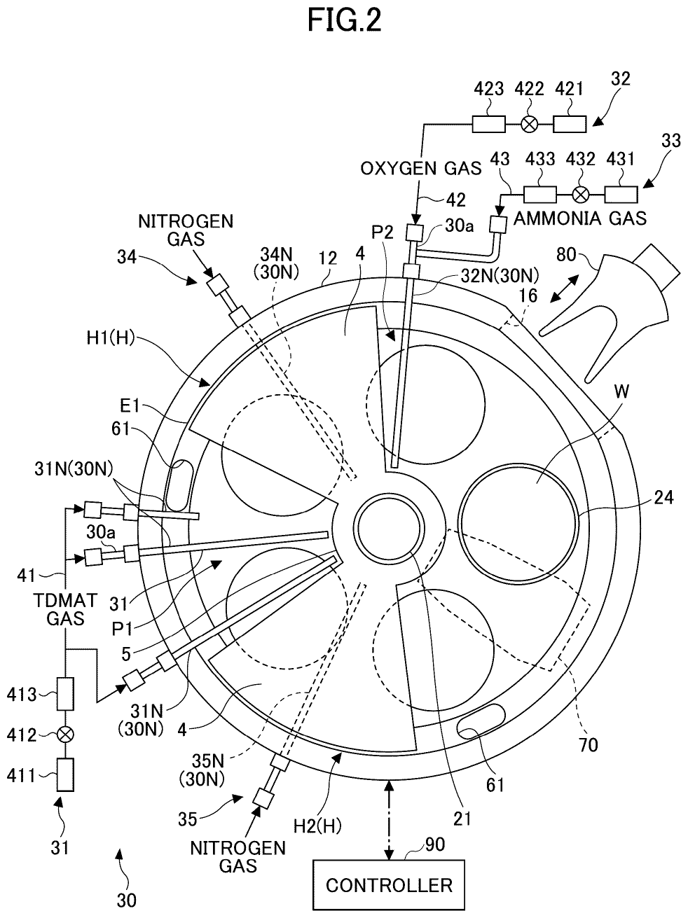

FIG. 1 is a cross-sectional view schematically illustrating a film-forming apparatus 100 according to an embodiment. FIG. 2 is a plan view schematically illustrating the interior of a process chamber 1 of the film-forming apparatus 100. As illustrated in FIGS. 1 and 2, the film-forming apparatus 100 according to the embodiment is a substrate-processing apparatus for forming a film on the surface of the substrate W through atomic layer deposition (ALD) or molecular layer deposition (MLD). The film-forming apparatus 100 includes: a process chamber 1 configured to house the substrate W and perform a film-forming process; and a rotation table 2 that is provided in the process chamber 1 so as to be rotatable.

The process chamber 1 is formed in a flat cylindrical shape, and includes a processing section housing the substrate W. For example, the process chamber 1 is formed by assembling a chamber body 12 having an open top surface and a top plate 11 disposed on the top of the chamber body 12. For the sake of convenience, illustration of the top plate 11 is omitted in FIG. 2. The chamber body 12 includes a disk-shaped bottom 14 and a side portion 13 projecting from the outer edge of the bottom 14 upward in the vertical direction. The side portion 13 and the top plate 11 of the chamber body 12 are hermetically fixed to each other via a sealing member 15, such as an O-ring or the like.

The rotation table 2 is formed in an annular shape, and the inner circumference thereof is fixed to a core 21 having a cylindrical shape. The core 21 is fixed to the upper end of a rotation shaft 22 extending in the vertical direction. The rotation shaft 22 penetrates the bottom 14 of the process chamber 1, and the lower end thereof is held by a driver 23. The driver 23 is configured to rotate the rotation shaft 22 about the axis thereof. Thereby, the rotation table 2 is rotated via the rotation shaft 22 and the core 21 about the center of the process chamber 1 serving as the center of rotation.

The rotation shaft 22 and the driver 23 are housed in a cylindrical casing 20 having an open top surface. The casing 20 includes a flange at the upper end thereof, and is hermetically fixed to the bottom 14 of the process chamber 1. Therefore, the internal space of the casing 20 is isolated from the exterior of the casing 20, and is communicated with the processing section of the process chamber 1.

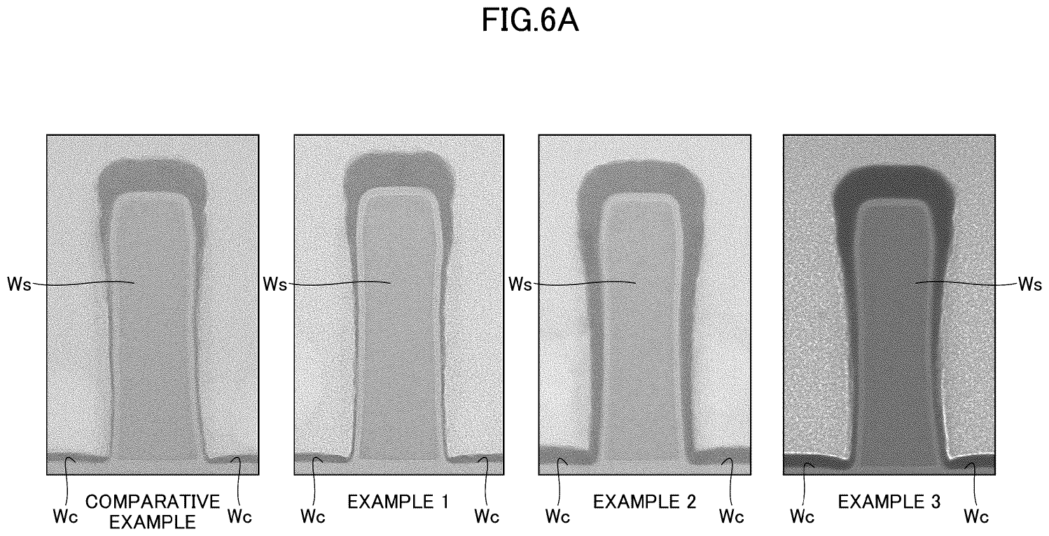

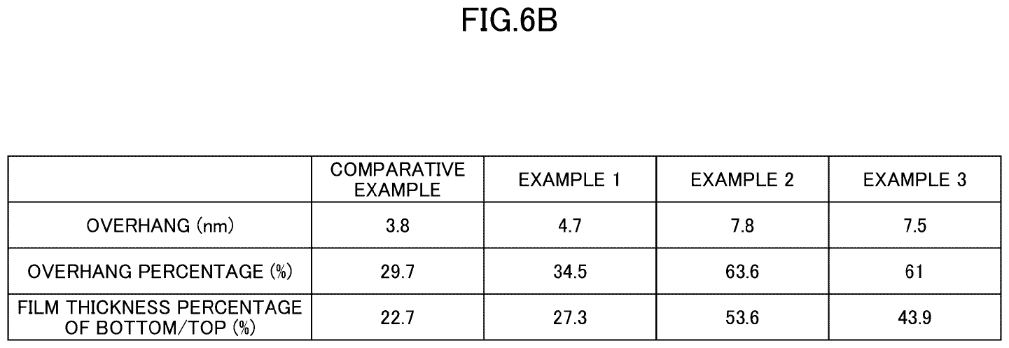

As illustrated in FIG. 2, the upper surface of the rotation table 2 is provided with a plurality of (five in FIG. 2) circular recessed stages 24 on which the substrate W can be placed. The recessed stages 24 are provided along the rotating direction of the rotation table 2. Examples of the substrate W to be subjected to a film-forming process include semiconductor wafers, such as silicon semiconductor wafers, compound semiconductor wafers, oxide semiconductor wafers, and the like. The substrate W may include, at the surface thereof, recesses Wc (e.g., a trench, a via, and the like) and projections Ws (see FIG. 6A).

The recessed stage 24 has an inner diameter slightly larger than the diameter of the substrate W (e.g., 300 mm) and a depth substantially equal to the thickness of the substrate W. Thereby, in a state in which the substrate W is placed on the recessed stage 24, the upper surface of the substrate W and the upper surface of the rotation table 2 (a region thereof in which the substrate W is not placed) become approximately the same in height.

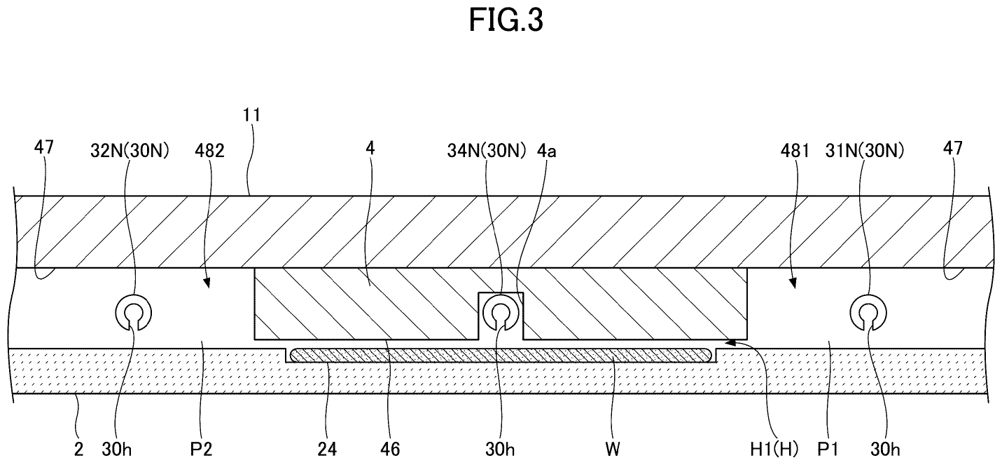

The film-forming apparatus 100 includes a gas supply 30 configured to supply gas into the process chamber 1. For example, the gas supply 30 includes a plurality of gas nozzles 30N that are formed of quartz and extend in the form of a straight line. Each of the gas nozzles 30N includes an introduction port 30a that a base end thereof and radially extends through the interior of the process chamber 1 to the vicinity of a center region. The introduction port 30a is fixed to the side portion 13 of the process chamber 1. The gas nozzle 30N extends parallel to the upper surface of the rotation table 2 in the process chamber 1. The gas nozzle 30N is provided with a plurality of gas discharge holes 30h that are open toward the rotation table 2, i.e., downward in the vertical direction (see also FIG. 3). The gas discharge holes 30h are arranged at equal intervals along the axial direction of the gas nozzle 30N (radial direction of the process chamber 1).

The gas supply 30 includes: a raw material gas supply 31 configured to supply a raw material gas; a reaction gas supply 32 configured to supply a reaction gas; a shape control gas supply 33 configured to supply a shape control gas, and a first separation gas supply 34 and a second separation gas supply 35 each configured to supply a separation gas. Also, the raw material gas supply 31 includes three raw material gas nozzles 31N as the gas nozzles 30N. The reaction gas supply 32 includes one reaction gas nozzle 32N as the gas nozzles 30N. The shape control gas supply 33 discharges the shape control gas utilizing the reaction gas nozzle 32N. The first separation gas supply 34 includes one first separation gas nozzle 34N as the gas nozzles 30N. The second separation gas supply 35 includes one second separation gas nozzle 35N as the gas nozzles 30N. In the process chamber 1 of the illustrated example, the one second separation gas nozzle 35N, the three raw material gas nozzles 31N, the one first separation gas nozzle 34N, and the one reaction gas nozzle 32N are arranged clockwise in this order from a transfer port 16 that is provided in the side portion 13.

The raw material gas supply 31 connects a raw material gas supply path 41 to the introduction port 30a of each of the raw material gas nozzles 31N, the introduction port 30a projecting outward of the process chamber 1. The raw material gas supply 31 includes a raw material gas supply 411, an opening/closing valve 412, a flow rate regulator 413, and the like in the raw material gas supply path 41.

The film-forming apparatus 100 according to the embodiment forms a titanium oxynitride (TiON) film on the surface of the substrate W. When the titanium oxynitride film is formed, the raw material gas supplied by the raw material gas supply 31 is a titanium-containing gas that contains titanium (Ti), which is a metal element. Examples of the titanium-containing gas include a tetrakis(dimethylamino) titanium (Ti[N(CH₃)₂]₄) gas, a titanium tetrachloride (TiCl₄) gas, a TiCp(NMe₂)₃ gas, a TiMe₅Cp(NMe₂)₃ gas, a tetraisopropyl titanate (Ti(OCH(CH₃)₂)₄) gas, and the like. In the embodiment, a tetrakis(dimethylamino) titanium gas is used as the titanium-containing gas (the tetrakis(dimethylamino) titanium gas is abbreviated as a TDMAT gas, and thus hereinafter may also be referred to as a TDMAT gas).

The three raw material gas nozzles 31N include a nozzle configured to supply the TDMAT gas near the center of the rotation table 2, a nozzle configured to supply the TDMAT gas to substantially the entirety of the rotation table 2 in the radial direction thereof, and a nozzle configured to supply the TDMAT gas near the outer circumference of the rotation table 2. Thus, the TDMAT gas can be adsorbed to the surface of the substrate W in an even distribution while the substrate W is moving along the circumferential direction of the rotation table 2.

The reaction gas supply 32 connects a reaction gas supply path 42 to the introduction port 30a of each of the reaction gas nozzles 32N, the introduction port 30a projecting outward of the process chamber 1. The reaction gas supply 32 includes a reaction gas supply source 421, an opening/closing valve 422, a flow rate regulator 423, and the like in the reaction gas supply path 42.

As the reaction gas supplied by the reaction gas supply 32, an oxidizing gas that reacts with TDMAT (titanium-containing precursor) adsorbed on the surface of the substrate W and oxidizes TDMAT is selected. In this embodiment, the reaction gas is an oxygen (O₂) gas.

The shape control gas supply 33 includes a shape control gas supply path 43 connected to a location partway along in the reaction gas supply path 42. The shape control gas supply 33 mixes the oxygen gas with the shape control gas from the reaction gas supply path 42, and then delivers the gas mixture to the introduction port 30a of the reaction gas nozzle 32N. The shape control gas supply 33 includes a shape control gas supply source 431, an opening/closing valve 432, a flow rate regulator 433, and the like in the shape control gas supply path 43.

As the shape control gas, a gas that reacts with titanium on the surface of the substrate W together with oxygen is selected. In this embodiment, the shape control gas is an ammonia (NH₃) gas. Shape control of the titanium oxynitride film by supplying the shape control gas will be described in detail below. The shape control gas supply 33 may include a shape control gas nozzle in the process chamber 1 separately from the reaction gas nozzle 32N, and may be configured to discharge the shape control gas from this shape control gas nozzle.

The first separation gas supply 34 connects an unillustrated separation gas supply path to the introduction port 30a of the first separation gas nozzle 34N, the introduction port 30a projecting outward of the process chamber 1. The first separation gas supply 34 includes an unillustrated separation gas supply source, an unillustrated opening/closing valve, an unillustrated flow rate regulator, and the like in this separation gas supply path. The second separation gas supply 35 connects an unillustrated separation gas supply path to the introduction port 30a of the second separation gas nozzle 35N, the introduction port 30a projecting outward of the process chamber 1. The second separation gas supply 35 includes an unillustrated separation gas supply source, an unillustrated opening/closing valve, an unillustrated flow rate regulator, and the like in this separation gas supply path.

The separation gas supplied by the first separation gas supply 34 and the second separation gas supply 35 is appropriately selected from noble gases, such as an argon (Ar) gas, a helium (He) gas, and the like, and inert gases, such as a nitrogen (Ne) gas and the like. In the embodiment, a nitrogen gas is applied as the separation gas.

Also, the process chamber 1 includes two projections 4 therein along the circumferential direction thereof. The projections 4 have a generally fan-like planar shape that is formed by being cut in an arc shape. In the embodiment, the inner arc of the projections 4 is connected to a below-described projection 5, and the outer arc of the projections 4 is disposed along the inner circumferential surface of the side portion 13 of the process chamber 1.

FIG. 3 is a partial cross-sectional view of a range of the process chamber 1 including the raw material gas nozzle 31N, the first separation gas nozzle 34N, and the reaction gas nozzle 32N, taken along the concentric circle of the rotation table 2. As illustrated in FIG. 3, the projections 4 are attached to the lower surface of the top plate 11. Therefore, the interior of the process chamber 1 includes: a flat ceiling surface 46, the lower surface of each of the projections 4; and a ceiling surface 47 that is higher than the ceiling surface 46. The ceiling surface 47 is located on both sides of the ceiling surface 46 in the circumferential direction.

A groove 4a extending along the radial direction of the rotation table 2 is formed in one of the projections 4. The first separation gas nozzle 34N is housed in this groove 4a. The groove 4a is similarly formed in the other projection 4, and the second separation gas nozzle 35N is housed in this groove 4a (see FIG. 2).

In FIG. 3, the raw material gas nozzle 31N is provided in a space 481 on the right-hand side of the projection 4 (the space below the higher ceiling surface 47 in the vertical direction). The reaction gas nozzle 32N is provided in a space 482 on the left-hand side of the projection 4 (the space below the higher ceiling surface 47 in the vertical direction). These gas nozzles 30N are provided near the substrate W and apart from the ceiling surface 47.

Meanwhile, the lower ceiling surface 46 forms a separation space H between the lower ceiling surface 46 and the rotation table 2, and the separation space H is a small space. The volume of the separation space H is smaller than the volume of the spaces 481 and 482. Thus, when the nitrogen gas (separation gas) is supplied through the first separation gas nozzle 34N, the nitrogen gas can increase the pressure of the separation space H compared to the pressure of the spaces 481 and 482. Thereby, the separation space H forms a pressure barrier between the spaces 481 and 482. Moreover, the nitrogen gas flowing out of the separation space H into the spaces 481 and 482 serves as a counterflow between the raw material gas and the reaction gas. Therefore, the raw material gas and the reaction gas are separated by the separation space H, thereby suppressing reaction caused by mixing of each other.

As illustrated in FIGS. 1 and 2, the projection 5 provided on the lower surface of the top plate 11 encloses the outer circumference of the core 21 configured to fix the rotation table 2. The projection 5 is continuous with a portion of the projection 4 closer to the center of rotation. The lower surface of the projection 5 is at the same height as that of the ceiling surface 46.

Gas exhaustion ports 61 are formed between the rotation table 2 and the side portion 13 of the chamber body 12. A gas exhaustion tube 630 is connected to the gas exhaustion ports 61. The gas exhaustion tube 630 is connected to a vacuum pump 640, serving as a vacuum gas exhauster, via a pressure adjuster 650.

A heater 7 serving as a heat generator is provided in the space between the bottom 14 of the process chamber 1 and the rotation table 2. The heater 7 is configured to heat the substrate W on the rotation table 2 to the target temperature (e.g., 225 degrees Celsius (° C.)) determined in accordance with a recipe. A cover 71 having an annular shape is provided below the rotation table 2 near the circumference thereof. The cover 71 is for suppressing entry of gas into the space below the rotation table 2.

The bottom 14 closer to the center of rotation than is the space in which the heater 7 is disposed is a projection 12a that projects upward so as to become closer to the core 21 at the center of the lower surface of the rotation table 2. The space between the projection 12a and the core 21 is a small space. Also, the gap between the rotation shaft 22 and the inner circumferential surface of the through-hole for the rotation shaft 22 penetrating the bottom 14 is narrow. This small space and this narrow gap are both in communication with the casing 20. A cover 7a is provided between the heater 7 and the rotation table 2. The cover 7a covers the region between the cover 71 and the upper end of the projection 12a in the circumferential direction. The cover 7a is formed of quartz or the like, and suppresses entry of gas into the heater 7.

The casing 20 is provided with a purge gas supply tube 72 through which a nitrogen gas, a purge gas (the same gas as the separation gas supplied by the first separation gas nozzle 34N), is supplied to the above small space and narrow gap. Further, a plurality of purge gas supply tubes 73 are provided at appropriate intervals along the circumferential direction at the bottom 14 below the heater 7. The purge gas supply tubes 73 are configured to purge the space in which the heater 7 is provided.

When the purge gas is supplied from the purge gas supply tube 72, the purge gas flows through the gap between the rotation shaft 22 and the inner circumferential surface of the through-hole for the rotation shaft 22, and then the gap between the projection 12a and the core 21. Subsequently, the purge gas flows through the space between the rotation table 2 and the cover 7a, and is exhausted from the gas exhaustion ports 61. When the purge gas is supplied from the purge gas supply tubes 73, the purge gas outflows through an unillustrated gap between the cover 7a and the cover 71 from the space in which the heater 7 is housed, and is exhausted from the gas exhaustion ports 61. The flow of the purge gas suppresses mixing of the raw material gas and the reaction gas in the space below the center of the process chamber 1 and in the space below the rotation table 2.

A separation gas supply tube 51 is connected to the center of the top plate 11 of the process chamber 1. The separation gas supply tube 51 supplies a nitrogen gas (the same gas as the separation gas supplied by the first separation gas nozzle 34N) to the space between the top plate 11 and the core 21. The nitrogen gas supplied to this space flows along the surface of the rotation table 2 through the small space between the projection 5 and the rotation table 2. The space between the projection 5 and the rotation table 2 is maintained at a high pressure by the nitrogen gas. This suppresses passage of the raw material gas and the reaction gas through a center region C, and mixing thereof.

Further, as illustrated in FIG. 2, the transfer port 16 is formed in the side wall of the process chamber 1. Through the transfer port 16, the substrate W is transferred between an external transfer arm 80 and the rotation table 2. The transfer port 16 is opened and closed by an unillustrated gate valve. Transfer of the substrate W between the recessed stage 24, a region of the rotation table 2 on which the substrate is to be placed, and the transfer arm 80 is performed at a position facing the transfer port 16. Therefore, the film-forming apparatus 100 includes an unillustrated raising and lowering pin and an unillustrated raising and lowering mechanism at a position below the rotation table 2 and next to the transfer port 16. The raising and lowering pin penetrates the recessed stage 24 and raises the substrate W from the back surface thereof.

Also, the film-forming apparatus 100 includes a controller 90 configured to control the components of the entire apparatus. The controller 90 is a computer including a processor, a memory, an input/output interface, and a communication interface, each of which are not illustrated. The processor is a combination of one or more of a CPU (Central Processing Unit), a GPU (Graphics Processing Unit), an ASIC (Application Specific Integrated Circuit), an FPGA (Field-Programmable Gate Array), a circuit formed of a plurality of discrete semiconductors, and the like, and is configured to execute a program stored in the memory. The memory includes a main storage formed of a semiconductor memory and the like, and an auxiliary storage formed of a disk, a semiconductor memory (flash memory), and the like.

Under the control of the controller 90, the above film-forming apparatus 100 supplies the TDMAT gas, the oxygen gas, the ammonia gas, and the nitrogen gas to the processing section of the process chamber 1. By supply of the nitrogen gas to the separation space H, the process chamber 1 can separate, in a plan view, a raw material gas processing space P1 to which the TDMAT gas is to be supplied, from a reaction gas processing space P2 to which the oxygen gas and the ammonia gas are to be supplied. Especially, the film-forming apparatus 100 supplies the oxygen gas and the ammonia gas to the reaction gas processing space P2 (the same area), thereby adjusting the shape of a titanium oxynitride film to be formed.

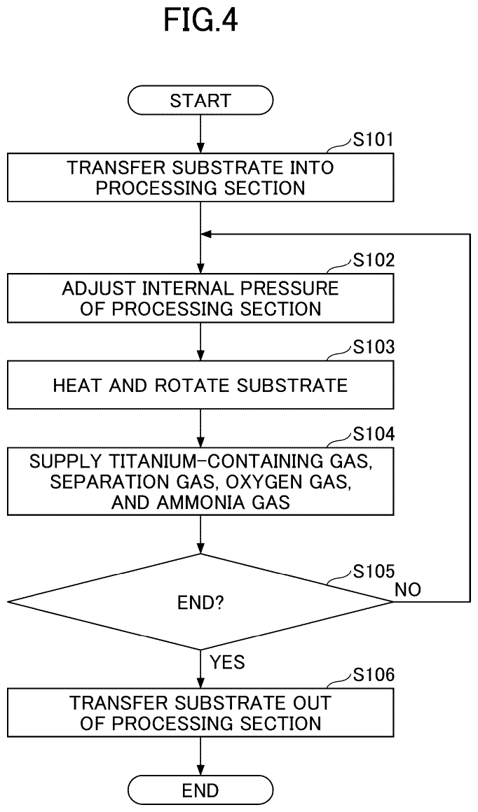

The film-forming apparatus 100 according to the embodiment is basically configured as described above. How the film-forming apparatus 100 works (film-forming method) will be described below with reference to FIG. 4. FIG. 4 is a flowchart of the film-forming method performed by the film-forming apparatus 100. The film-forming apparatus 100 performs steps S101 to S106 as illustrated in FIG. 4 under the control of the controller 90.

Specifically, the controller 90 first opens the gate valve, transfers the substrate W through the transfer port 16 (FIG. 2) by the transfer arm 80, and places the substrate W on the recessed stage 24 of the rotation table 2 (step S101). At this time, the controller 90 intermittently rotates the rotation table 2 and sequentially places the substrates W on the corresponding recessed stages 24. After the transfer of the substrates W, the controller 90 closes the gate valve, thereby achieving a hermetically closed state of the process chamber 1.

When the process chamber 1 is hermetically closed, the controller 90 performs preliminary preparation for the film-forming process. The controller 90 discharges the nitrogen gas from the first separation gas nozzle 34N and the second separation gas nozzle 35N, and exhausts the gas by the vacuum pump 640 and the pressure adjuster 650, thereby adjusting the internal pressure of the entire processing section of the process chamber 1 to the target pressure (step S102). At this time, the controller 90 may also discharge the nitrogen gas from the separation gas supply tube 51 and the purge gas supply tubes 72 and 73.

As further preliminary preparation for the film-forming process, the controller 90 heats the substrate W to the target temperature by the heater 7 and rotates the rotation table 2 clockwise at the target rotational speed (step S103). During the film-forming process, the film-forming apparatus 100 maintains the target pressure, temperature, and rotational speed that are set in steps S102 and S103. The target pressure, temperature, and rotational speed may be changed in accordance with the contents (recipe) of the film-forming process.

Upon completion of the preliminary preparation, the controller 90 supplies the TOMAT gas, the nitrogen gas, the oxygen gas, and the ammonia gas from the gas supply 30 to the process chamber 1, and performs the film-forming process on each of the substrates W that are rotated by the rotation table 2 (step S104). The TDMAT gas is separated from the oxygen gas and the ammonia gas in the separation space H (first separation space H1 and second separation space H2) of the two projections 4 that are supplying the nitrogen gas, thereby avoiding mixing thereof in the process chamber 1.

The above step S104 includes a step of supplying the TOMAT gas to the raw material gas processing space P1 from the raw material gas supply 31 (step (A)). When the substrate W passes through the raw material gas processing space P1 by rotation of the rotation table 2, the TDMAT gas (titanium-containing precursor) supplied from the raw material gas nozzle 31N is adsorbed on the surface of the substrate W.

When the substrate W of the rotation table 2 passes through the first separation space H1 after the raw material gas processing space P1, the nitrogen gas is supplied from the first separation gas nozzle 34N. Thereby, the TDMAT gas existing around the substrate W is removed. Also, the nitrogen gas flows to the raw material gas processing space P1 and the reaction gas processing space P2 around the projection 4 while increasing the pressure of the first separation space H1, thereby separating these spaces from each other.

Further, step S104 includes a step of supplying the oxygen gas to the reaction gas processing space P2 from the reaction gas supply 32, and supplying the ammonia gas to the reaction gas processing space P2 from the shape control gas supply 33 (step (B)). That is, when the substrate W of the rotation table 2 is moved to the reaction gas processing space P2 after the first separation space H1, a gas mixture of the oxygen gas and the ammonia gas is supplied from the reaction gas nozzle 32N. For example, the gas supply 30 supplies the oxygen gas to the reaction gas processing space P2 at 6,000 sccm. For example, the gas supply 30 supplies the ammonia gas to the reaction gas processing space P2 at 1,000 sccm. Thereby, the reaction gas processing space P2 becomes in a state in which large amounts of the oxygen gas and the ammonia gas are mixed together.

As a result, in the reaction gas processing space P2, the titanium precursor on the surface of the substrate W reacts with oxygen and ammonia. Ammonia is decomposed to a nitrogen atom and hydrogen atoms, and reacts with titanium. Also, oxygen is decomposed to oxygen atoms, and reacts with titanium. Thereby, a titanium oxynitride film is formed on the surface of the substrate W.

Especially, by supplying the oxygen gas and the ammonia gas to the same reaction gas processing space P2, it is possible to suppress excessive formation of titanium oxide through the reaction of titanium with oxygen. The ammonia gas changes the shape of the film on the recess Wc and the projection Ws of the substrate W in accordance with the amount of the ammonia gas supplied (see also FIGS. 6A and 6B). The functions of the ammonia gas will be described below.

When the substrate W of the rotation table 2 passes through the second separation space H2 after the reaction gas processing space P2, the nitrogen gas is supplied from the second separation gas nozzle 35N. This removes the oxygen gas, the ammonia gas, and the reaction by-products remaining on the surface of the substrate W. Also, the nitrogen gas flows to the raw material gas processing space P1 and the reaction gas processing space P2 around the projection 4 while increasing the pressure of the second separation space H2, thereby separating these spaces from each other. After passing through the second separation space H2, the substrate of the rotation table 2 returns to the raw material gas processing space P1 again.

In step S105, the controller 90 determines whether or not to continue the film-forming process. In the case in which the film-forming process is continued (step S105: NO), the process returns to step S102, and then the same process flow is repeated. Thereby, the titanium oxynitride film is gradually deposited on the surface of the substrate W. For example, the controller 90 monitors the duration during which the film-forming process is performed, and determines the end of the film-forming process when the target duration has passed (step S105: YES). The target duration is set in accordance with the target film thickness of the titanium oxynitride film. When the controller 90 determines the end of the film-forming process, the controller 90 stops the supply of each gas to the process chamber 1 and the rotation of the rotation table 2, and transfers the substrate W from the process chamber 1 in reversed order of the procedure of transferring the substrate W into the process chamber 1 (step S106). Thus, the film-forming process is ended.

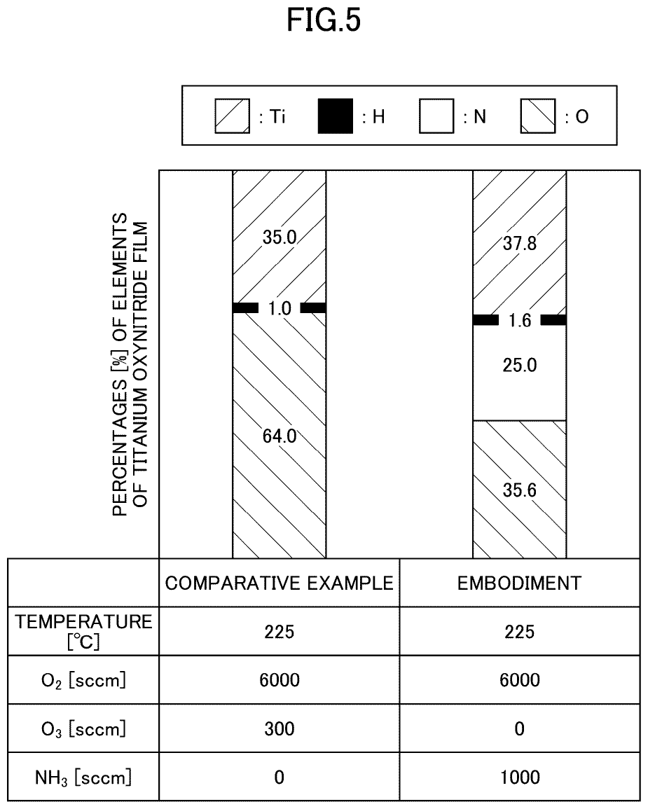

FIG. 5 is a graph illustrating the percentages of the elements of the titanium oxynitride film formed by the film-forming method. In FIG. 5, the left-hand bar of the graph indicates the concentration ratios of the titanium oxide film according to a comparative example in which no ammonia gas is supplied, and the right-hand bar of the graph indicates the concentration ratios of the titanium oxynitride film formed by the film-forming method as described above.

In the comparative example, the titanium oxide film was formed on the surface of the substrate by supplying the oxygen gas and an ozone (03) gas as the reaction gas, followed by plasma processing. In this titanium oxide film, the concentration of titanium is 35% while the concentration of oxygen is high, i.e., 64%. Also, in the substrate W including the recesses Wc and the projections Ws, the concentration of oxygen tends to be higher near the projecting ends of the projections Ws. Therefore, the titanium oxide film is likely to be formed in a shape (helmet shape) in which the thickness of the projecting ends of the projections Ws becomes larger.

Meanwhile, according to the film-forming method according to the embodiment, the titanium oxynitride film is formed on the surface of the substrate W through the process of mixing and supplying the oxygen gas and the ammonia gas. Especially, according to the film-forming method according to the embodiment, the amount of the ammonia gas to be supplied is smaller than the amount of the oxygen gas to be supplied. As a result, in the titanium oxynitride film according to the embodiment, the concentration of oxygen is 35.6% while the concentration of nitrogen is 258. That is, according to the film-forming method as described above, it is possible to ensure the percentage of oxygen included in the titanium oxynitride film while suppressing inclusion of nitrogen in the titanium oxynitride film at a high concentration. The concentration of titanium in the titanium oxynitride film is 37.8%. Thus, oxygen and nitrogen are included at an appropriate ratio in the titanium oxynitride film formed by the film-forming method according to the embodiment.

Further, in the substrate W including the recesses Wc and the projections Ws, the concentration of nitrogen tends to be high in the middle portion of each projection Ws. Therefore, according to the film-forming method, the shape of the titanium oxynitride film formed in the recesses Wc and the projections Ws of the substrate W can be controlled by appropriately adjusting the amount of the oxygen gas including oxygen atoms and the amount of the ammonia gas including nitrogen atoms.

FIG. 6A is enlarged cross-sectional views each illustrating the projection Ws of the substrate W on which the film is formed. FIG. 6B is a graph obtained by analyzing the state of the film formed at the projection Ws. In FIGS. 6A and 6B, the comparative example is the same as the titanium oxide film illustrated in the comparative example of the graph in FIG. 5, and Examples 1 to 3 are titanium oxide films obtained by varying the amount of the oxygen gas supplied and the amount of the ammonia gas supplied. Specifically, in Example 1, the amount of the oxygen gas supplied was set to 6,000 sccm, and the amount of the ammonia gas supplied was set to 1,000 sccm. Therefore, in Example 1, the ratio of the amount of the ammonia gas supplied to the amount of the oxygen gas supplied is ⅙. In Example 2, the amount of the oxygen gas supplied was set to 6,000 sccm, and the amount of the ammonia gas supplied was set to 100 sccm. Therefore, in Example 2, the ratio of the amount of the ammonia gas supplied to the amount of the oxygen gas supplied is 1/60. In Example 3, the amount of the oxygen gas supplied was set to 500 sccm, and the amount of the ammonia gas supplied was set to 100 sccm. Therefore, in Example 3, the ratio of the amount of the ammonia gas supplied to the amount of the oxygen gas supplied is ⅕. In Examples 1 to 3, the process conditions other than the amounts of the oxygen and ammonia gases are the same.

The overhang in FIG. 6B refers to the length of the formed film projecting laterally (in the direction orthogonal to the projection Ws) relative to the width of the projecting end of the projection Ws of the substrate W. The overhang percentage in FIG. 6B refers to a ratio of the overhang relative to the thickness, in the height direction, of the film formed on the projection Ws of the substrate W. The film thickness percentage of bottom/top in FIG. 6B refers to a ratio between the film thickness of the projecting end and the film thickness of the bottom in the film formed on the projection Ws of the substrate W.

As understood from FIGS. 6A and 6B, the shape of the titanium oxynitride film formed on the projection Ws of the substrate W is changed by varying the amount of the oxygen gas supplied and the amount of the ammonia gas supplied or by varying the ratio of the amount of the ammonia gas supplied and the amount of the oxygen gas supplied. For example, Example 1 can be regarded as a pattern in which the amount of the oxygen gas supplied and the amount of the ammonia gas supplied are relatively large, and the ratio of the amounts of these gases supplied is small. It can be regarded in Example 1 that the overhang on the projection Ws of the substrate W is suppressed, and the titanium oxynitride film having a larger thickness with respect to the surface of the projecting end of the projection Ws is formed.

Meanwhile, Example 2 can be regarded as a pattern in which the amount of the oxygen gas supplied is relatively large while the amount of the ammonia gas supplied is small, in other words, the ratio of the amounts of these gases supplied is large. It can be regarded in Example 2 that the difference in the film thickness of the formed titanium oxynitride film is small along the height direction of the projection Ws of the substrate W (the film thickness ratio of bottom/top is large), i.e., the thickness of the formed titanium oxynitride film is approximately uniform.

Accordingly, in the film-forming method according to the embodiment, it is preferable to adjust the amount of the oxygen gas supplied, the amount of the ammonia gas supplied, and the ratio of the amounts of these gases supplied, in accordance with the target shape of the titanium oxynitride film to be formed on the projection Ws of the substrate W. For example, upon forming a shape (helmet shape) in which the film thickness of the titanium oxynitride film is large with respect to the surface of the projecting end of the projection Ws and is small with respect to the side surface of the projection Ws, the amount of the ammonia gas to be supplied is increased in the film-forming method. That is, the ratio of the amount of the ammonia gas to be supplied and the amount of the oxygen gas to be supplied is reduced. However, even if the ratio of the amounts of these gases supplied is small as in Example 3, when the amount of the oxygen gas supplied and the amount of the ammonia gas supplied are both small, the overhang becomes larger.

Upon forming the helmet shape, it is preferable to set the amount of the oxygen gas to be supplied and the amount of the ammonia gas to be supplied to be, for example, in the range of from 1,000 sccm through 10,000 sccm. The ratio of the amount of the ammonia gas supplied to the amount of the oxygen gas supplied is set to be, for example, in the range of from about ⅓ through about 1/10. Thereby, the helmet shape of the titanium oxynitride film can be accurately formed.

Meanwhile, in order to achieve a film thickness having high uniformity (conformal film thickness) over the entire surface of the projection Ws, the amount of the ammonia gas to be supplied is reduced in the film-forming method, and the ratio of the amount of the oxygen gas to be supplied and the amount of the ammonia gas to be supplied is increased. For example, the ratio of the amount of the ammonia gas to be supplied to the amount of the oxygen gas to be supplied is set to be, for example, in the range of from about 1/30 through about 1/100. Preferably, the amount of the oxygen gas to be supplied is set in the range of from 1,000 sccm through 10,000 sccm, and the amount of the ammonia gas to be supplied is set in the range of from 10 sccm through 500 sccm. Thereby, a titanium oxynitride film having a film thickness conformal with respect to the projection Ws can be accurately formed.

As described above, the film-forming apparatus 100 and the film-forming method can form a titanium oxynitride film on the projection Ws of the substrate W so as to have an appropriate shape. In other words, the ammonia gas to be mixed with the oxygen gas and supplied can appropriately control the shape of the titanium oxynitride film in accordance with the amount thereof supplied and the ratio of the amounts thereof supplied.

The film-forming apparatus 100 and the film-forming method are not limited to the above embodiments, and can take various modified examples. For example, according to the film-forming apparatus 100 according to the above embodiment, the oxygen gas and the ammonia gas are supplied to the reaction gas processing space P2 of the process chamber 1, followed by causing reaction through heating. However, this is by no means a limitation. For example, the film-forming apparatus 100 may be configured to generate a plasma in the reaction gas processing space P2, thereby performing plasma processing on the substrates W. For example, the film-forming apparatus 100 may include a plasma generator 70 at a position indicated by a dotted line in the reaction gas processing space P2 of FIG. 2. Also, when the film-forming apparatus 100 generates a plasma in the reaction gas processing space P2, an ozone gas may be included as a gas to be supplied to the reaction gas processing space P2, in addition to the oxygen gas and the ammonia gas. By forming the ozone gas into a plasma in the plasma generator 70, it is possible to supply oxygen radicals to the substrates W.

For example, the film-forming apparatus 100 is not limited to the configuration in which the substrates W are rotated (orbited) in the circumferential direction by the rotation table 2. For example, the film-forming apparatus 100 may employ a configuration in which the substrates W are rotated by the rotation table 2 while each of the substrates W itself is spinning. The film-forming apparatus 100 may be a single-wafer type apparatus in which the film-forming process is performed on a single substrate W, or may be a batch-type apparatus in which a plurality of substrates are arranged in a longitudinal or transverse direction such that the planes of the substrates W face each other. When the film-forming apparatus 100 is a single-wafer type apparatus or a batch-type apparatus, the effects the same as described above can be obtained by separating, over time, the step of supplying the titanium-containing gas (TDMAT gas) and the step of simultaneously supplying the oxidizing gas (oxygen gas) and the shape control gas (ammonia gas).

The technical ideas and effects of the present disclosure as described in the above embodiments will be described below.

A first aspect of the present disclosure is the film-forming method for forming the titanium oxynitride film on the substrate W. This film-forming method includes: (a) supplying the titanium-containing gas to the substrate W; and (b) supplying the oxidizing gas to the substrate W to which the titanium-containing gas is supplied, and supplying the shape control gas to the area the same as the area to which the oxidizing gas is supplied, thereby adjusting the shape of the titanium oxynitride film.

The above film-forming method can readily form the titanium oxynitride film into the target shape by supplying the oxidizing gas and the shape control gas to the same area. Also, the titanium oxynitride film formed on the surface of the substrate W is, for example, softer than a titanium oxide film. Thus, the titanium oxynitride film can be readily peeled. In other words, the above film-forming method can readily form a titanium oxynitride film that has the target shape and is readily processible even after formation of the film.

In step (b), the amount of the shape control gas to be supplied is smaller than the amount of the oxidizing gas to be supplied. Thus, the film-forming method can suppress the titanium oxynitride film from containing the shape control gas at a high concentration, and ensure the percentage of oxygen included in the titanium oxynitride film.

The surface of the substrate W includes the recesses Wc, and the projections Ws that are formed between the recesses Wc, and in step (b), the shape of the titanium oxynitride film formed on the projections Ws is adjusted by changing the amount of the shape control gas to be supplied. Thereby, the film-forming method can appropriately form the titanium oxynitride film on the projections Ws.

Also, upon forming a shape of the titanium oxynitride film in which the film thickness of the titanium oxynitride film on the projecting ends of the projections Ws is large and the film thickness of the titanium oxynitride film on the side surfaces of the projections Ws is small, in step (b), the ratio of the amount of the shape control gas to be supplied to the amount of the oxidizing gas to be supplied is set to be in the range of from ⅓ through 1/10. Thereby, the film-forming method can successfully form the titanium oxynitride film having a larger thickness on the projecting ends of the projections Ws.

Upon forming a titanium oxynitride film having high uniformity on the projecting ends and the side surfaces of the projections Ws, in step (b), the ratio of the amount of the shape control gas to be supplied to the amount of the oxidizing gas to be supplied is set to be in the range of from 1/30 through 1/100. Thereby, the film-forming method can form a titanium oxynitride film having a conformal film thickness on the projecting ends and the side surfaces of the projections Ws.

The shape control gas is an ammonia gas. By applying the ammonia gas as the shape control gas, the film-forming method can readily control the titanium oxynitride film into the target shape.

The oxidizing gas is an oxygen gas. Thereby, the film-forming method can efficiently form a titanium oxynitride film through the reaction between the oxygen gas and the ammonia gas in the same area (reaction gas processing space P2).

A second aspect of the present disclosure is the film-forming apparatus 100 for forming the titanium oxynitride film on the substrate W. The film-forming apparatus 100 includes the raw material gas supply 31 configured to supply the titanium-containing gas to the substrate W; the reaction gas supply 32 configured to supply the oxidizing gas to the substrate W to which the titanium-containing gas is supplied; and the shape control gas supply 33 configured to supply the shape control gas to the area the same as the area to which the oxidizing gas is supplied, thereby adjusting the shape of the titanium oxynitride film. Even in this case, the film-forming apparatus 100 can readily form the titanium oxide film into the target shape.

Also, the film-forming apparatus 100 further includes the process chamber 1; and the rotation table 2 that is provided in the process chamber 1 so as to be rotatable and on which the substrates W are to be placed. In this film-forming apparatus 100, the raw material gas supply 31 is configured to supply the titanium-containing gas to the raw material gas processing space P1 provided in the circumferential direction of the rotation table 2, and the reaction gas supply 32 and the shape control gas supply 33 are configured to supply the oxidizing gas and the shape control gas to the reaction gas processing space P2 provided at a position different from the raw material gas processing space P1 in the circumferential direction of the rotation table 2. Thereby, the film-forming apparatus 100 can perform the film-forming method while rotating the substrates W, and can successfully form the titanium oxynitride film on the substrates W.

The film-forming apparatus 100 and the film-forming method according to the embodiments disclosed herein are illustrative in all respects and not restrictive. The embodiments may be modified and improved in various forms without departing from the scope and the subject of the claims recited. The matters described in the above embodiments can take other configurations to the extent that there is no contradiction, and can be combined together to the extent that there is no contradiction.

According to one embodiment, it is possible to provide a technique of readily forming a titanium oxynitride film into a target shape.

What is claimed is:

1. A film-forming method for forming a titanium oxynitride film on a substrate, the film-forming method comprising:
(a) supplying a titanium-containing gas to the substrate; and
(b) supplying an oxidizing gas to the substrate to which the titanium-containing gas is supplied, and supplying a shape control gas to an area same as that to which the oxidizing gas is supplied, thereby adjusting a shape of the titanium oxynitride film.

2. The film-forming method according to claim 1, wherein
in (b), an amount of the shape control gas to be supplied is smaller than an amount of the oxidizing gas to be supplied.

3. The film-forming method according to claim 1, wherein
a surface of the substrate includes
a plurality of recesses, and
a plurality of projections that are formed between the recesses, and
in (b), the shape of the titanium oxynitride film formed on the projections is adjusted by changing an amount of the shape control gas to be supplied.

4. The film-forming method according to claim 3, wherein
upon forming a shape of the titanium oxynitride film in which a film thickness of the titanium oxynitride film on projecting ends of the projections is large and a film thickness of the titanium oxynitride film on side surfaces of the projections is small, in (b), a ratio of an amount of the shape control gas to be supplied to an amount of the oxidizing gas to be supplied is set to be in a range of from ⅓ through 1/10.

5. The film-forming method according to claim 3, wherein
upon forming the titanium oxynitride film having high uniformity on projecting ends and side surfaces of the projections, in (b), a ratio of an amount of the shape control gas to be supplied to an amount of the oxidizing gas to be supplied is set to be in a range of from 1/30 through 1/100.

6. The film-forming method according to claim 2, wherein
a surface of the substrate includes
a plurality of recesses, and
a plurality of projections that are formed between the recesses, and
in (b), the shape of the titanium oxynitride film formed on the projections is adjusted by changing the amount of the shape control gas to be supplied.

7. The film-forming method according to claim 6, wherein
upon forming a shape in which a film thickness of the titanium oxynitride film on projecting ends of the projections is large and a film thickness of the titanium oxynitride film on side surfaces of the projections is small, in (b), the ratio of the amount of the shape control gas to be supplied to the amount of the oxidizing gas to be supplied is set to be in a range of from ⅓ through 1/10.

8. The film-forming method according to claim 6, wherein
upon forming the titanium oxynitride film having high uniformity on projecting ends and side surfaces of the projections, in (b), the ratio of the amount of the shape control gas to be supplied to the amount of the oxidizing gas to be supplied is set to be in a range of from 1/30 through 1/100.

9. The film-forming method according to claim 1, wherein
the shape control gas is an ammonia gas.

10. The film-forming method according to claim 2, wherein
the shape control gas is an ammonia gas.

11. The film-forming method according to claim 1, wherein
the oxidizing gas is an oxygen gas.

12. The film-forming method according to claim 2, wherein
the oxidizing gas is an oxygen gas.

13. A film-forming apparatus for forming a titanium oxynitride film on a substrate, the film-forming apparatus comprising:
a raw material gas supply configured to supply a titanium-containing gas to the substrate;
a reaction gas supply configured to supply an oxidizing gas to the substrate to which the titanium-containing gas is supplied; and
a shape control gas supply configured to supply a shape control gas to an area same as that to which the oxidizing gas is supplied, thereby adjusting a shape of the titanium oxynitride film.

14. The film-forming apparatus according to claim 13, further comprising:
a process chamber; and
a rotation table that is provided in the process chamber so as to be rotatable and on which a plurality of substrates each being the substrate are to be placed, wherein
the raw material gas supply is configured to supply the titanium-containing gas to a raw material gas processing space provided in a circumferential direction of the rotation table, and
the reaction gas supply and the shape control gas supply are configured to supply the oxidizing gas and the shape control gas to a reaction gas processing space provided at a position different from the raw material gas processing space in the circumferential direction of the rotation table.
